(19) United States
(12) Patent Application Publication
(10) Pub. No.: US 2015/0114290 A1
(43) Pub. Date: Apr. 30, 2015

(54) ORGANIC THIN FILM FORMATION DEVICE

(71) Applicant: ULVAC, Inc., Chigasaki-shi (JP)

(72) Inventors: Kazuhiko SAITOU, Chigasaki-shi (JP); Masayuki IIJIMA, Chigasaki-shi (JP); Takayoshi HIRONO, Chigasaki-shi (JP); Kenji NAKAMORI, Chigasaki-shi (JP)

(73) Assignee: ULVAC, Inc., Chigasaki-shi (JP)

(21) Appl. No.: 14/584,200

(22) Filed: Dec. 29, 2014

Related U.S. Application Data
(63) Continuation of application No. PCT/JP2013/066804, filed on Jun. 19, 2013.

(30) Foreign Application Priority Data
Jun. 29, 2012 (JP) 2012-147691

(51) Int. Cl. C23C 14/12; C23C 14/58

(52) U.S. Cl. CPC C23C 14/12; C23C 14/58
USPC 118/719

(57) ABSTRACT

The present invention forms an organic thin film at a high film formation rate by vapor of an organic compound generated by heating. A film formation chamber is disposed in the interior of a buffer chamber; a part of the side surface of a center roller is inserted in the film formation chamber from a film formation chamber opening; and a base material film is run in close contact with the side surface in the part. The vapor is carried by a carrier gas from a vapor generation device connected to the film formation chamber; the center roller is cooled by a cooling device; the base material film is cooled to temperatures lower than the condensation temperature of the vapor; and an organic raw material layer is formed on the surface of the base material film by the vapor discharged into the film formation chamber, which is cured by the irradiation with an energy ray in the curing chamber while rotating the center roller. The buffer chamber is evacuated to a low pressure so that the carrier gas and the vapor that flowed out of the film formation chamber opening do not flow into the curing chamber and the roll chamber.

This application is a continuation of International Application No. PCT/JP2013/066804, filed Jun. 19, 2013, which claims priority to Japan Patent Application No. 2012-147691, filed on Jun. 29, 2012. The contents of the prior applications are herein incorporated by reference in their entireties.

### BACKGROUND

The present invention generally related to an organic thin film formation device, in particular, to an organic thin film formation device for forming an organic thin film on a film in a vacuum atmosphere.

A thin film formation device that forms an organic thin film on a film in a vacuum atmosphere has been used conventionally; and a film for food packing or a film for electronic parts is produced by formation of a metal thin film or an organic thin film on a film.

The device is shown in FIG. 5. An organic thin film formation device 101 has a vacuum chamber 111; and, in the vacuum chamber 111, an original material roll 102 obtained by winding a base material film 105 to be film formed and a winding device 103 that winds up the base material film 105 unwound from the original material roll 102 are disposed.

In order to form an organic thin film on the base material film 105, first, the base material film 105 is unwound from the original material roll 102, and the leading edge of the unwound portion is attached to the winding device 103, whereby the rear surface of the base material film 105 is made to contact a part of the side surface of a center roller 104 disposed in the center of the vacuum chamber 111.

The interior of the vacuum chamber 111 is evacuated by a vacuum pump 109; the center roller 104 is rotated so that the base material film 105 and the surface of the center roller 104 do not slide each other; the base material film 105 is unwound from the original material roll 102; and the unwound base material film 105 is wound by the winding device 103.

A vapor production device 106 is disposed in a position facing the portion where the center roller 104 and the base material film 105 are in contact with each other; and when heating an organic material disposed in the vapor production device 106 by a heating device 107, vapor of the organic material is produced in the vapor production device 106 and the vapor of the organic material is discharged from a discharge port of the vapor production device 106 toward the center roller 104. In the position facing the discharge port, the base material film 105 moves while making contact with the center roller 104, the vapor of the organic material reaches the surface of the base material film 105 during movement in the position facing the discharge port, and an organic thin film is formed on the surface thereof, which is wound by the winding device 103 to thereby give a wound roll 108.

However, in the above-described organic thin film formation device 101, curing of the organic material is insufficient, and a technology for accelerating the curing reaction before the winding is required.

Furthermore, the technology is needed to have the thickness of the organic thin film formed on the base material film 105 be uniform and the interior of the vacuum chamber 111 be not polluted by the organic material vapor discharged inside the vacuum chamber 111.

### SUMMARY OF THE INVENTION

The present invention has been created in order to solve the disadvantage of the conventional technology, and a purpose thereof is to provide such an organic thin film formation device that does not pollute the interior of a vacuum chamber by the vapor, and forms a cured organic thin film at a high film formation rate.

In order to solve the above-described problem, the present invention is a thin film formation device which includes a vacuum chamber, a vapor discharge device, an energy ray-emitting device, an unwinding device, a winding device and a cylindrical center roller, and in which an original material roll of a base material film mounted on the unwinding device is unwound, during a time when the unwound base material film runs in the vacuum chamber while the rear surface thereof is in contact with the side surface of the center roller and is wound by the winding device, vapor of an organic compound discharged from a discharge port of the vapor discharge device into the vacuum chamber reaches the surface of the base material film in a portion in contact with the side surface of the center roller to thereby deposit an organic raw material layer, then the organic raw material layer is irradiated with an energy ray emitted from an emission part of the energy ray-emitting device, and the organic compound in the organic raw material layer chemically reacts to thereby form an organic thin film, wherein a configuration is such that: a vapor generation device generating vapor of the organic compound and supplying the vapor to the vapor discharge device is disposed in the exterior of the vacuum chamber; a buffer chamber is disposed in the interior of the vacuum chamber; a curing chamber is disposed in the interior of the vacuum chamber and in the exterior of the buffer chamber;

a film formation chamber is disposed in the interior of the buffer chamber; each of the buffer chamber, the film formation chamber and the curing chamber is connected to an evacuation device; the discharge port is disposed in the interior of the film formation chamber; the emission part is disposed in the curing chamber; the center roller is disposed so as to rotate around a rotation axis line positioned in the buffer chamber; a film formation chamber opening is provided in a portion positioned between the rotation axis line and the discharge port in a film formation chamber partition wall forming the film formation chamber and the discharge port and a side surface of the center roller face each other; and a curing chamber opening is provided in a portion positioned between the rotation axis line and the emission part in a curing chamber partition wall forming the curing chamber, and the emission part and a side surface of the center roller face each other.

In addition, the present invention is a thin film formation device configured so that a cooling device is connected to the center roller and the cooling device circulates a cooling medium between the center roller and the cooling device to thereby cool the center roller.

Furthermore, the present invention is a thin film formation device, wherein a portion of a side surface of the center roller, facing the discharge port is inserted into the interior of the film formation chamber from the film formation chamber opening, and a portion of a side wall of the center roller, facing the emission part is inserted into the interior of the curing chamber from the curing chamber opening.

Moreover, the present invention is a thin film formation device, further including a carrier gas supply device for supplying a carrier gas to the vapor generation device, wherein a mixed gas obtained by mixing the carrier gas and vapor of the organic compound is discharged from the discharge port.

In addition, the present invention is a thin film formation device, which is evacuated by the evacuation device so that the pressure of the film formation chamber is made higher than pressure of the buffer chamber, and that the pressure of the curing chamber is made lower than the buffer chamber.

In the present invention, since a vapor generation chamber is disposed in the exterior of a vacuum chamber and an opening of the film formation chamber is disposed in the interior of the buffer chamber, replenishment of an organic compound is easy and the vapor generated from the organic compound does not flow into the curing chamber or the roll chamber.

Since the center roller is cooled to the vapor condensation temperature or less, the vapor of an organic compound formed by heating can be condensed (solidification of gas is assumed to be included in addition to liquefaction of gas); and since the organic raw material layer formed by the condensation is cured with the energy resin, a tough organic thin film can be obtained.

Furthermore, the generated vapor is carried by a carrier gas; and thus, a large amount of vapor can be supplied to the film formation chamber from the vapor generation chamber and a film formation rate can be accelerated.

Moreover, since the formation of the organic raw material layer and the curing of the organic raw material layer are preformed by one center roller, the volume of the vacuum chamber can be reduced.

### BRIEF DESCRIPTION OF THE DRAWINGS

FIG. 1 is a drawing for explaining the thin film formation device of the present invention.

FIG. 2(a) and FIG. 2(b) are drawings for explaining a discharge port.

FIG. 3(a) is a drawing for explaining an opening of a film formation chamber; and FIG. 3(b) is a drawing for explaining an opening of a curing chamber.

FIG. 4(a) is a drawing showing a state where an organic raw material layer is formed on a base material film; and FIG. 4(b) is a drawing showing a state where an organic thin film of polymer is formed from the organic raw material layer.

FIG. 5 is a thin film formation device of a conventional technology.

### DETAILED DESCRIPTION OF THE INVENTION

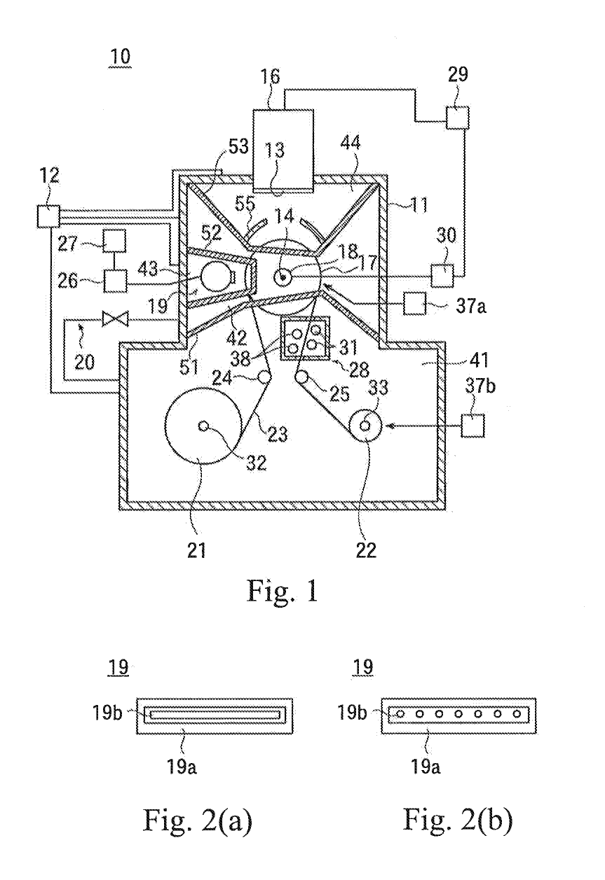

FIG. 1 shows a thin film formation device 10 of the present invention.

The thin film formation device 10 has a vacuum chamber 11; the interior of the vacuum chamber 11 is partitioned by a partition plate 51; and a roll chamber 41 is formed on one side of the partition plate 51 in the interior of the vacuum chamber 11.

A buffer chamber 42 is formed on the opposite side of the partition plate 51. A film formation chamber partition wall 52 is disposed in the interior of the buffer chamber 42; and a film formation chamber 43 separated from the interior space of the buffer chamber 42 is formed by the film formation chamber partition wall 52. The numeral 20 is a valve for pressure control between the roll chamber 41 and the buffer chamber 42.

Furthermore, a curing chamber partition wall 53 is disposed in a position separated from the film formation chamber 43 in the interior of the buffer chamber 42; and a curing chamber 44 separated from the interior space of the buffer chamber 42 is formed in the interior of the buffer chamber 42, by the curing chamber partition wall 53. The film formation chamber 43 and the curing chamber 44 are also separated from each other.

A center roller 17 that is constituted of a metal and has a cylindrical shape is disposed in the interior of the buffer chamber 42. Here, a rotation shaft 18 is disposed horizontally in the interior of the buffer chamber 42, and is configured such that the center roller 17 is attached to the rotation shaft 18 by making the central axis line thereof and the central axis line of the rotation shaft 18 coincide with each other, and such that the rotation shaft 18 and the center roller 17 rotate together around the coincident central axis line. Reference numeral 14 in FIG. 1 is the rotation axis line serving as the rotation center of the rotation shaft 18 and the center roller 17 and is also the central axis line of the rotation shaft 18 and the center roller 17.

The roll chamber 41, the film formation chamber 43 and the curing chamber 44 are disposed around the side surface of the center roller 17.

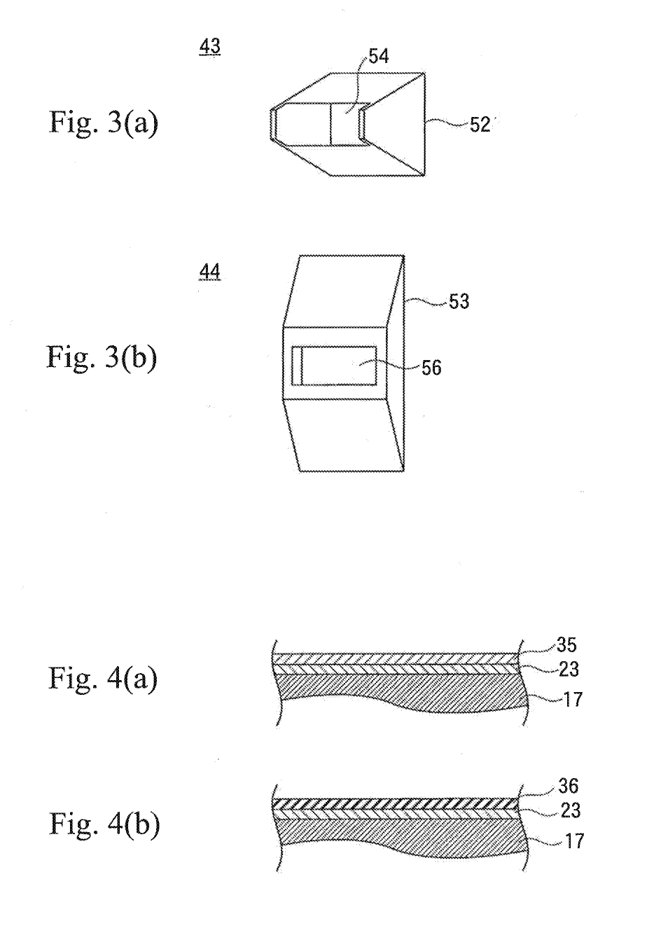

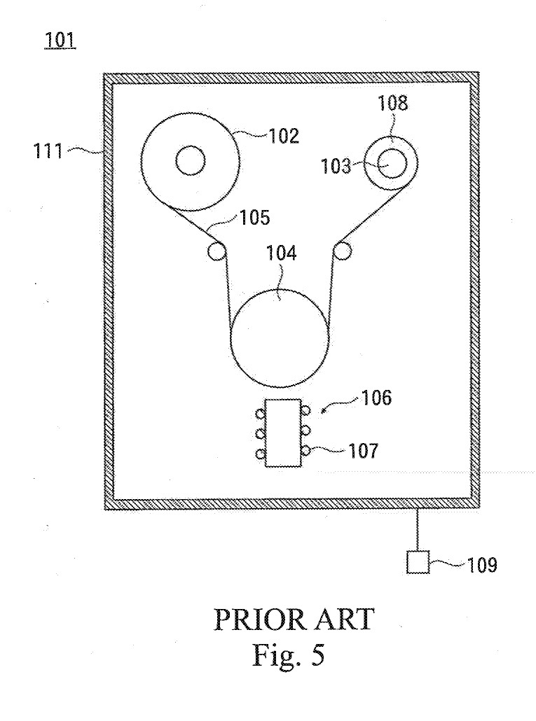

As shown in FIG. 3(a), a film formation chamber opening 54 is formed in the film formation chamber partition wall 52; and as shown in FIG. 3(b), a curing chamber opening 56 is formed in the curing chamber partition wall 53.

Each of the width of the film formation chamber opening 54, the width of the curing chamber opening 56 and the width of a passing port to be described below is set to be a little larger than the width of the side surface of the center roller 17 (distance between bottom faces). As to the side surface of the center roller 17, a part of the circumferential direction (that is, the whole part of the width direction thereof) is inserted in the film formation chamber 43, and another part of the circumferential direction of the side surface of the central roller 17 (that is, the whole part of the width direction thereof) is inserted in the curing chamber 44. The side surfaces of the inserted parts are exposed in the interior of the film formation chamber 43 and the curing chamber 44.

An unwinding device 32 and a winding device 33 are disposed in the interior of the roll chamber 41.

An original material roll 21 configured by winding a base material film 23 of a long sheet to be film-formed is mounted on the unwinding device 32, and first, the end portion of the base material film 23 positioned in the periphery of the original material roll 21 is extracted for winding the base material film 23 of the original material roll 21 by the winding device 33.

A passing port is formed in the partition plate 51. The top of the extracted portion passes through the passing port, then the direction thereof is changed by a roll 24, and is carried in the interior of the buffer chamber 42, comes into contact with the side surface of the center roller 17, moves along the circumferential direction of the side surface, passes through the interior of the film formation chamber 43, the interior of the buffer chamber 42, the interior of the curing chamber 44 and the interior of the buffer chamber 42, is returned to the roll chamber 41, then the direction thereof is changed by a roll 25, and is fixed to the winding device 33.

The center roller 17 is set so as not to contact the partition place 51, the film formation chamber partition wall 52 and the curing chamber partition wall 53.

Motors 37a and 37b are provided respectively at the rotation shaft 18 and the winding device 33.

The unwinding device 32 is rotatably configured; and when the rotation shaft 18 and center roller 17, and the winding device 33 are rotated respectively by the motors 37a and 37b, the original material roll 21 is pulled by the unwound base material film 23 and is rotated together with the unwinding device 32, and the base material film 23 is further unwound from the original material roll 21. The unwound portion is wound by the winding device 33 so that no slack is generated in the base material film 23.

When forming an organic thin film on the surface of the base material film 23, first, the interior of the vacuum chamber 11 is evacuated by the evacuation device 12.

The evacuation device 12 is connected individually to the roll chamber 41, the buffer chamber 42, the film formation chamber 43, and the curing chamber 44; and thus, each of chambers 41 to 44 is set to be capable of being individually evacuated.

Furthermore, each of chambers 41 to 44 is continuously evacuated after the formation of a vacuum atmosphere in each of chambers 41 to 44; and in the explanation below, a vacuum atmosphere is formed in each of chambers 41 to 44 and the evacuation is assumed to be continuously performed.

A vapor discharge device 19 is disposed in the interior of the film formation chamber 43.

A vapor generation device 26 is disposed in the exterior of the vacuum chamber 11; and the vapor discharge device 19 is connected to the vapor generation on device 26.

The vapor generation device 26 has a heating device and a vessel in which a liquid or solid organic compound is disposed, and is configured so as to heat little by little the organic compound disposed in the vessel by a heating device to thereby generate vapor.

Here, the organic compound is evaporated or sublimated by the heating to thereby produce a gas. In the present invention, the gas produced by the sublimation is assumed to be included in “vapor.”

A carrier gas supply device 27 that supplies a carrier gas (a gas that does not react with an organic compound such as rare gases and N₂ gas) is disposed to the vapor generation device 26, which is configure a so as to be capable of supplying a carrier gas that is heated and raised to a prescribed temperature from the carrier gas supply device 27 to the interior of the vapor generation device 26.

The vapor of an organic compound is generated in the inferior of the vapor generation device 26 while the carrier gas is being supplied, and the mixing of the generated vapor with the carrier gas produces a mixed gas and the mixed gas is carried to the vapor discharge device 19 by the difference in pressures between the vapor discharge device 19 and the vapor generation device 26.

An example of the vapor discharge device is shown in FIG. 2(a).

The vapor discharge device 19 has a discharge device main body 19a with a hollow interior and a long and narrow discharge port 19b provided in the discharge device main body 19a. The mixed gas of a vapor and a carrier gas supplied from the vapor discharge device 19 spreads uniformly in the discharge device main body 19a, and is uniformly discharged inside the film formation chamber 43 from the discharge port 19b.

The discharge port 19b is disposed in a position facing the side surface of the center roller 17 in a stare where the longitudinal direction is in parallel with the rotation axis line 14; and the base material film 23 is positioned between the discharge port 19b and the center roller 17.

The length of the discharge port 19b in the longitudinal direction is set to be longer than the width of the base material film 23; and thus, both ends of the discharge port 19b protrude to the outside of the width direction of the base material film 23.

When vapor is discharged from the discharge port 19b together with a carrier gas, the vapor reaches the range including both ends of the width direction of the base material film 23.

As shown in FIG. 2(b), the discharge port 19b of a circular opening may also be arranged in one line or a plurality of lines in parallel with the width direction of the base material film 23 in a range longer than the width of the base material film 23.

In a part facing the discharge port 19b in the side surface of the center roller 17, the rear surface of the base material film 23 positioned between the center roller 17 and the discharge port 19b is in contact with the side surface of the center roller 17, and the vapor discharged from the discharge port 19b reaches the part in which the rear surface is in contact with the center roller 17, on the base material film 23.

Respective portions of the surface of the base material film 23 is in contact with the center roller 17 before being moved to a position where the vapor discharged from the discharge port 19b reaches and is cooled by the center roller 17, as will be described later; and the temperature of the cooled base material film 23 is set to be a temperature at which the partial pressure of the vapor near the surface of the base material film 23 of a portion where the vapor reaches becomes higher than the saturated vapor pressure by the interior pressure of the film formation chamber 43.

Accordingly, the vapor that reaches the surface of the base material film 23 condenses into a liquid or gas; and an organic raw material layer composed of the vapor condensed on the surface of the base material film 23 is deposited. FIG. 4(a) shows a state where an organic raw material layer 35 is deposited on the base material film 23.

An organic compound of a monomer is disposed within the vapor generation device 26, and the vapor thereof is a gaseous monomer. Accordingly, the organic raw material layer 35 is a monomer layer composed of the monomer.

As to the base material film 23, after being fed out from the original material roll 21 and before the deposition of the organic raw material layer 35, the rear surface is in contact with the center roller 17; and as described above, when the center roller 17 and the winding device 33 rotate to thereby move the base material film 23, the center roller 17 and the winding device 33 rotate so as to move the base material film 23 without the scratch of the rear surface, in a state where the rear surface is in contact with the side surface of the center roller 17.

The base material film 23 on which the organic raw material layer 35 has been deposited is carried out from the film formation chamber 43 in a state where the rear surface is in contact with the center roller 17, passes through the buffer chamber 42 and, after that, is carried into the interior of the curing chamber 44.

The curing chamber 44 is provided with an energy ray-emitting device 16.

The energy ray-emitting device 16 has an emission part 13; and is configured such that emission part 13 is disposed in the curing chamber 44 and an energy ray is emitted from the emission part 13 to the interior of the curing chamber 44.

The organic raw material layer 35 on the surface of the base material film 23 that is in contact with the side surface of the center roller 17 inserted in the interior of the curing chamber 44 is irradiated with the emitted energy ray.

The range of the base material film 23 irradiated with the energy ray is in the shape of a straight line along the width direction of the base material film 23 (that is, is in the shape of a straight line extending in the direction perpendicular to the moving direction of the base material film 23); and the base material film 23 is irradiated over a range wider than that in the width direction. The width of the irradiation range is constant; and the organic raw material layer 35 is irradiated with the width of the energy ray in the whole position in the width direction, when passing through the irradiation position.

In the portions of the organic raw material layer 35 having been irradiated with the energy ray, a polymerization reaction of monomers is generated by the energy the energy ray has, the monomer is made into a polymer by the progress of the polymerization reaction, and thus an organic thin film of polymer from the organic raw material layer 35 is formed. Reference numeral 36 in FIG. 4(b) shows the organic thin film.

Here, the energy ray includes electrons, but may be a ray that radiates another elemental particle or charged particle, or radiates an electromagnetic wave (including light).

However, when an energy ray has an electric charge, an irradiated base material film 23 is charged. In the present invention, the center roller 17 is connected to the ground potential, and is thus configured such that electric charges to be accumulated on the organic thin film 36 or the base material film 23 by the irradiation with the energy ray flow out from the center roller 17 to the ground potential to thereby reduce the charges.

A cooling device 30 is provided to the center roller 17, and the cooling device 30 is configured so as to circulate a cooling medium between the cooling device 30 and the center roller 17, and to cause the cooled cooling medium to flow into a flow path in the interior of the center roller 17 to thereby cool the center roller 17.

The rear surface of the base material film 23 is in contact with the portion inserted in the interior of the film formation chamber 43 in the side surface of the center roller 17 in the interior of the film formation chamber 43 and in contact with the portion inserted in the interior of the curing chamber 44 in the interior of the curing chamber 44; and the rear surface of the base material film 23 is in contact with the identical center roller 17 during the time from before the formation of the organic raw material layer 35 until after the formation of the organic thin film 36. During such time, the base material film 23 is cooled by the center roller 17 and moves while being cooled.

The heat caused by the vapor reached the base material film 23 or by the energy ray with which the base material film 23 and the organic raw material layer 35 have been irradiated raises the temperature of the cooling medium flowing through the flow path of the center roller 17 and the cooling medium having a raised temperature is returned to the cooling device 30.

In the cooling device 30, the heat of the cooling medium is released to be cooled, and the cooled cooling medium is carried to be circulated into the center roller 17.

It is sufficient that the base material film 23 makes contact with the center roller 17 and cooled to a temperature for condensation before condensing the vapor of an organic compound; and the position in which the contact is started may be any position of the interior of the roll chamber 41, the interior of the buffer chamber 42, and the interior of the film formation chamber 43.

The base material film 23 of the portion in which the organic thin film 36 is formed passes through the curing chamber opening 56 while the rear surface thereof is in contact with the center roller 17, is carried out from the curing chamber 44, is carried into the buffer chamber 42, passes through the buffer chamber 42, passes through the passing port formed in the partition plate 51, and is carried into the roll chamber 41.

When a charged particle (such as, an electron) is emitted toward the base material film 23, the base material film 23 becomes charged, and the base material film 23 may be adsorbed to the center roller 17 by the electrostatic force of the charge when the base material film 23 is separated from the center roller 17, and the base material film 23 may be caught in the center roller 17 due to failure in the separation.

In the present invention, since a neutralization device 28 is provided in the vicinity of a position in which the base material film 23 is separated from the center roller 17, plasma formed by the neutralization device 28 is spread over a separation position and thus, the charged amount before the separation is decreased.

The separation position should be disposed in a chamber in which the neutralization device 28 is disposed, which in this case is the roll chamber 41.

After being separated from the center roller 17 in the roll chamber 41, the base material film 23 of the portion in which the organic thin film 36 is formed passes through plasma formed by the neutralization device 28 to be neutralized, and is wound up by the winding device 33. Accordingly, the base material film 23 on which the organic thin film 36 is formed is not charged, and the winding device 33 having wound the same is also not charged and there is no adsorption of the base material film 23 caused by the charging.

As described above, the vapor of the monomer discharged from the vapor discharge device 19 adheres to the base material film 23 by condensation and the organic raw material layer 35 is formed. Furthermore, the organic raw material layer 35 is cured and formed into the organic thin film 36 by the generation of a polymerization reaction through irradiation of the organic raw material layer 35 with an energy ray. During such time, the rear surface of the base material film 23 is in contact with the identical center roller 17, and the base material film 23 on which the organic thin film 36 is formed can be obtained with one center roller 17. In this case, after the base material film 23 has come into contact with the center roller 17, the base material film 23 and the center roller 17 are not separated during the period when they are separated after the formation of the organic thin film 36.

As to the vacuum atmosphere of the film formation chamber 43, the film formation chamber 43 is disposed in the interior of the buffer chamber 42, and the interior of the buffer chamber 42 and the interior of the film formation chamber 43 is separated from each other by the film formation chamber partition wall 52 and the tank wall of the vacuum chamber 11. The interior of the buffer chamber 42 and the interior of the film formation chamber 43 are connected to each other only by the film formation chamber opening 54, and portions other than the film formation chamber opening 54 are shielded.

The vacuum atmosphere of the curing chamber 44 is connected to the vacuum atmosphere of the buffer chamber 42 by the curing chamber opening 56; and the vacuum atmosphere of the roll chamber 41 is connected to the vacuum atmosphere of the buffer chamber 42 by the passing port of the partition plate 51. However, the film formation chamber opening 54 is disposed in the interior of the buffer chamber 42, and it is configured such that the vapor and the carrier gas that flow out from the film formation chamber opening 54 are evacuated by the evacuation device 12 that evacuates the buffer chamber 42 so as to prevent the vapor and the carrier gas from flowing into the curing chamber 44 and the roll chamber 41.

When a member that controls all the devices provided in the film formation chamber 43 of the present invention is referred to as a control device 29, the individual evacuation rate of each of chambers 41 to 44 of the evacuation device 12 and the supply amount of the carrier gas to the vapor generation device 26 are controlled by the control device 29. Furthermore, with the use of the control device 29 and the evacuation device 12, the evacuation is performed so that the pressure of the film formation chamber 43 is made to be higher than the pressure of the buffer chamber 42 and the pressure of the curing chamber 44 is made to be lower than the pressure of the buffer chamber 42.

When each chamber is to be evacuated, the evacuation is to be performed so that the pressure of the roll chamber 41 becomes higher than the pressure of the buffer chamber 42, and the vapor of the organic compound that has flowed into the buffer chamber 42 from the film formation chamber opening 54 of the film formation chamber 43 is evacuated from the buffer chamber 42 to thereby prevent it from flowing into the curing chamber 44 and the roll chamber 41 from the curing chamber opening 56 and the passing port. A gas-introducing device may be provided in the roll chamber 41 thereby permit an inert gas to be introduced.

A temperature sensor is provided in the interior of the center roller 17, and the control device 29 measures the temperature of the center roller 17 by the temperature sensor; and it is thus possible to control the cooling device 30 so that the temperature of the center roller 17 falls within a prescribed range, and to control the temperature of the base material film 23 when the organic raw material layer 35 is formed and the temperature of the base material film 23 when the organic raw material layer 35 is cured to thereby form the organic thin film 36.

In addition, the control device 29 may control the energy ray-emitting device 16, the neutralization device 28, the vapor generation device 26, or the like.

In the above-described example, motors 37a and 37b are connected to the rotation shaft 18 and the winding device 33, but it may be configured such that the rotation force of the motor assists the rotation of the original material roll 21 by connecting a motor also to the unwinding device 32.

The supply amount of the carrier gas is flow rate-controlled by a mass flow device the carrier gas supply device 27 has and the control device 29 controls; and thus, the grow speed of the organic raw material layer 35 on the base material film 23 can be controlled by the control device 29.

The above-described evacuation device 12 may be provided with a plurality of vacuum pumps and the pressure of each of chambers 41 to 44 may be independently controlled by connecting the independent vacuum pump to each of the chambers 41 to 44.

Furthermore, in the Example, a mask plate 55 is provided in the interior of the curing chamber 44 and the base material film 23 is irradiated with the energy ray having passed through the opening of the mask plate 55, and the base material film 23 located other than the position to be irradiated is prevented from being exposed to the energy ray.

In the neutralization device 28, a set 31 of an electrode for applying a positive voltage and an electrode for applying a negative voltage is disposed and a magnet 38 for shutting in plasma is disposed, in the interior of a housing.

In the above-described monomer, organic compounds capable of being polymerized by the irradiation with an energy ray and capable of forming an organic thin film are widely included.

The related art of the present invention are JPA 2000-508089, JPA 2010-236076, and JPB 3502261.

### DESCRIPTION OF REFERENCE NUMERAL

11. vacuum chamber
12. evacuation device
14. rotation axis line
17. center roller
19b. discharge port
21. original material roll
23. bass material film
26. vapor generation device
27. carrier gas supply device
30. cooling device
32. unwinding device
33. winding device
35. organic raw material layer
36. organic thin film
41. roll chamber
42. buffer chamber
43. film formation chamber
44. curing chamber
54. film formation chamber opening
56. curing chamber opening

What is claimed is:

1. A thin film formation device, comprising:
a vacuum chamber;
a vapor discharge device;
an energy ray-emitting device;
an unwinding device;
a winding device; and
a cylindrical center roller, wherein an original material roll of a base material film mounted on the unwinding device is unwound, during a time when the unwound base material film runs in the vacuum chamber while a rear surface thereof is in contact with a side surface of the center roller and is wound by the winding device, vapor of an organic compound discharged from a discharge port of the vapor discharge device into the vacuum chamber reaches a surface of the base material film in a portion in contact with the side surface of the center roller to thereby deposit an organic raw material layer, then the organic raw material layer is irradiated with an energy ray emitted from an emission part of the energy ray-emitting device, and the organic compound in the organic raw material layer chemically reacts to thereby form an organic thin film, the thin film formation device, further comprising:
a vapor generation device, disposed in the exterior of the vacuum chamber, that generates vapor of the organic compound and supplies the vapor to the vapor discharge device;
a buffer chamber disposed in the interior of the vacuum chamber;
a curing chamber disposed in the interior of the vacuum chamber and in the exterior of the buffer chamber; and
a film formation chamber disposed in the interior of the buffer chamber;
each of the buffer chamber, the film formation chamber and the curing chamber being connected to an evacuation device,
the discharge port being disposed in the interior of the film formation chamber,
the emission part being disposed in the curing chamber, and
the center roller is disposed so as to rotate around a rotation axis line positioned in the buffer chamber,
wherein a film formation chamber opening is provided in a portion positioned between the rotation axis line and the discharge port in a film formation chamber partition wall forming the film formation chamber and the discharge port and a side surface of the center roller face each other, and
wherein a curing chamber opening is provided in a portion positioned between the rotation axis line and the emission part in a curing chamber partition wall forming the curing chamber, and the emission part and a side surface of the center roller face each other.

2. The thin film formation device according to claim 1, wherein a cooling device is connected to the center roller, to circulate a cooling medium between the center roller and the cooling device, and to cool the center roller.

3. The thin film formation device according to claim 1, wherein:
a portion of a side surface of the center roller, facing the discharge port, is inserted into the interior of the film formation chamber from the film formation chamber opening, and
a portion of a side wall of the center roller, facing the emission part, is inserted into the interior of the curing chamber from the curing chamber opening.

4. The thin film formation device according to claim 2, wherein:
a portion of a side surface of the center roller, facing the discharge port, is inserted into the interior of the film formation chamber from the film formation chamber opening, and
a portion of a side wall of the center roller, facing the emission part, is inserted into the interior of the curing chamber from the curing chamber opening.

5. The thin film formation device according to claim 1, further comprising:
a carrier gas supply device for supplying a carrier gas to the vapor generation device, wherein
a mixed gas obtained by mixing the carrier gas and vapor of the organic compound is discharged from the discharge port.

6. The thin film formation device according to claim 2, further comprising:
a carrier gas supply device for supplying a carrier gas to the vapor generation device, wherein
a mixed gas obtained by mixing the carrier gas and vapor of the organic compound is discharged from the discharge port.

7. The thin film formation device according to claim 1, which is evacuated by the evacuation device so that pressure of the film formation chamber is made higher than pressure of the buffer chamber, and so that a pressure of the curing chamber is made lower than the buffer chamber.

8. The thin film formation device according to claim 2, which is evacuated by the evacuation device so that pressure of the film formation chamber is made higher than pressure of the buffer chamber, and so that a pressure of the curing chamber is made lower than the buffer chamber.

9. The thin film formation device according to claim 5, which is evacuated by the evacuation device so that pressure of the film formation chamber is made higher than pressure of the buffer chamber, and so that a pressure of the curing chamber is made lower than the buffer chamber.

10. The thin film formation device according to claim 6, which is evacuated by the evacuation device so that pressure of the film formation chamber is made higher than pressure of the buffer chamber, and so that a pressure of the curing chamber is made lower than the buffer chamber.
